(19) United States
(12) Patent Application Publication
(10) Pub. No.: US 2008/0217619 A1
(43) Pub. Date: Sep. 11, 2008

(54) THIN FILM TRANSISTOR AND DISPLAY DEVICE

(75) Inventor: Hiroyuki Shimada, Chuo-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/042,766

(22) Filed: Mar. 5, 2008

(30) Foreign Application Priority Data
Mar. 9, 2007 (JP) 2007-059652
Jan. 28, 2008 (JP) 2008-016538

(51) Int. Cl. H01L 33/00

(52) U.S. Cl. 257/59; 257/E33.001

(57) ABSTRACT

The fully depleted thin film transistor (TFT) formed on a semiconductor film (103) on an insulator (101) is, in order to improve characteristics of the fully depleted thin film transistor, formed including a gate electrode formed over the semiconductor film having a gate insulating film (107) therebetween, source-drain regions (111) formed in the semiconductor film at both sides of the gate electrode, a channel region (CH) located between the source-drain regions (111), and a body contact region (113) adjacent to the channel region. A substrate floating effect can be reduced, even if the gate electrode is miniaturized, by providing a body contact region so as to withdraw excess carriers generated in the channel region through the body contact region.

This application claims priority from Japanese Patent Application No. 2007-059652, filed on Mar. 9, 2007, and from Japanese Patent Application No. 2008-16538, filed on Jan. 28, 2008, the contents of which are incorporated herein.

### 1. TECHNICAL FIELD

The present invention relates to a thin film transistor and a display device.

### 2. RELATED ART

Driving a partially depleted MOS (Metal Oxide Semiconductor) transistor with a high drain voltage results in a punch-through phenomenon caused by a function of a parasitic bipolar originated from a substrate floating effect, and therefore, the MOS transistor, formed on a so-called SOI (Silicon-On-Insulator) substrate with unfixed body potential, becomes inoperable.

It is common to prevent defects in a breakdown voltage by providing a body contact. In other words, a breakdown voltage can be improved (a punch-through phenomenon can be avoided) by the body contact that withdraws excess carriers being generated. Examples of such a technique are disclosed in Japanese Unexamined Patent Application Publication No. 114734 and Japanese Unexamined Patent Application Publication No. 9-246562.

On the other hand, a switching element used in a panel that has an active matrix structure of a liquid crystal device is called a thin film transistor (TFT: Thin Film Transistor), and has a body floating structure in which the body potential is not fixed.

The inventor of the invention is engaged in research and development related to improving characteristics of display devices using liquid crystal and the like, and thin film transistors used in those display devices.

As described, the switching element (TFT) used in a panel that has an active matrix structure has a body floating structure in which the body potential is not fixed. Moreover, a relatively high threshold value is set in this TFT, in order to sufficiently reduce an off-leak. Thus an impurity concentration of a channel region is sufficiently low, and the body region becomes completely depleted. What is generally known is that such a fully depleted MOS transistor has a very high body resistance, so that carrier removal has no effect even if the body contact structure is employed.

On the other hand, since known TFTs have relatively large gate lengths, and include polycrystalline silicon that accumulates therein less carriers, the substrate floating effect has occurred less, and no operational problem has been generated even without employing the body contact structure.

Nevertheless, in light of improving an operating speed and reducing power consumption, there is an increasing demand for the miniaturization of TFTs. According to the study of the inventor, such an instance leads to a problem that merely reducing the gate length of the TFT still generates the substrate floating effect described above, and thus a desired TFT operation cannot be obtained. Particularly, since TFTs used for display devices are driven in high potential drain voltages, unlike fully depleted MOS transistors that are intended for a low voltage drive, the substrate floating effect occurs eminently, thereby becoming a problem.

### SUMMARY

The object of the invention is to improve characteristics of a fully depleted TFT. In particular, the object is to provide a fully depleted TFT structure which is capable of being driven in a high potential drain voltage, while complying with the miniaturization.

(1) According to the invention, a thin film transistor which is fully depleted includes: an insulator; a gate electrode; a semiconductor film located between the insulator and the gate electrode; and a gate insulating film located between the semiconductor film and the gate electrode; the semiconductor film including a source region, a drain region, a channel region located between the source region and the drain region, as well as a body contact region adjacent to the channel region, wherein a gate width of the gate electrode is not greater than five times a gate length, and a source-drain potential of the thin film transistor is greater than or equal to 3V.

Such a structure allows the fully depleted thin film transistor to withdraw excess carriers generated in the channel region via the body contact region, thereby reducing the substrate floating effect. In particular, miniaturizing the gate electrode allows driving in a high potential drain voltage.

Even if, for instance, the gate width is reduced, excess carriers generated in the channel region can be withdrawn, thereby reducing the substrate floating effect. Moreover, an operation is possible even if there is a high potential greater than or equal to 3V between the source and the drain.

The insulator is, for instance, an insulating substrate. Therefore, an insulating substrate such as a glass substrate may be used.

The insulator is, for instance, a translucent substrate. Therefore, a translucent substrate such as a glass substrate may be used.

The semiconductor film is, for instance, a single-crystalline silicon film. Therefore, a single-crystalline silicon film may be used.

The semiconductor film is, for instance, a polycrystalline silicon film. Therefore, a polycrystalline silicon film may be used.

For example, one of a common potential and a predetermined potential is applied to the body contact region. Therefore, a potential of the body region can be fixed.

It is preferable that the gate width of the gate electrode be not more than three times the gate length. Such a structure allows the further reduction of the substrate floating effect.

The gate width of the gate electrode is, for instance, equal to or smaller than 3 μm. As such, even a fine thin film transistor can be operated in a high potential drain voltage.

The source-drain potential of the thin film transistor is greater than or equal to 5V. Consequently, an operation is possible even if there is a high potential greater than or equal to 5V between the source and the drain.

The gate electrode is characterized by having one of a T-gate structure and an H-gate structure. Conserving the symmetrical property of the thin film transistor therefore allows the usage of, for instance, a drive method of the common structure.

(2) According to the invention, a display device includes: a thin film transistor which is fully depleted; a gate wiring; a source wiring; and a pixel electrode, wherein the thin film transistor includes a semiconductor film, a gate electrode, and a gate insulating film located between the semiconductor film and the gate electrode, the semiconductor film including a source region, a drain region, a channel region located between the source region and the drain region, and a body contact region adjacent to the channel region; the gate wiring electrically couples the gate electrode; the source wiring electrically couples the source region; and the pixel electrode electrically couples the drain region.

Such a structure allows the fully depleted thin film transistor in a thin film transistor section to withdraw excess carriers generated in the channel region via the body contact region, thereby reducing the substrate floating effect. Consequently, properties of the display device can be improved. For instance, the gate electrode is miniaturized, enabling a high-speed operation. Moreover, even if the gate electrode is miniaturized, operation in a high potential drain voltage is possible.

(3) According to the invention, a display device including a pixel region having a plurality of pixels and a peripheral circuit region in which a circuit for driving the pixels is formed, the display device includes: a first thin film transistor which is fully depleted and is coupled between a pixel electrode and a wiring, the first thin film transistor arranged to each of the pixels; and a second thin film transistor constituting the circuit, wherein the first and the second thin film transistors each include a gate electrode formed over a semiconductor film on an insulator, a gate insulating film included therebetween, a source and a drain regions formed in the semiconductor film at both sides of the gate electrode, and a channel region located between the source and the drain regions; and while the first thin film transistor includes a body contact region adjacent to the channel region, the second thin film transistor does not include the body contact region.

With such a structure, properties of the thin film transistor section in the pixel region can be improved. For instance, the gate electrode is miniaturized, enabling a high-speed operation. Moreover, even if the gate electrode is miniaturized, operation in a high potential drain voltage is possible. Further, a structure in a peripheral circuit region configured with transistors having relatively large gate widths does not have a body contact region, so that, for instance, a common circuit layout can be used as is, without increasing the surface area of the peripheral circuit unit.

### BRIEF DESCRIPTION OF THE DRAWINGS

FIG. 1 is a plan view illustrating a structure of a thin film transistor (TFT) according to a first embodiment.

FIG. 2A and FIG. 2B are sectional views illustrating a structure of the thin film transistor (TFT) according to the first embodiment.

FIG. 3 is a plan view illustrating a structure of the thin film transistor (TFT) according to the first embodiment.

FIG. 4A and FIG. 4B are sectional views illustrating a structure of the thin film transistor (TFT) according to the first embodiment.

FIG. 5 is a diagram illustrating a transfer characteristic of a thin film transistor (TFT) according to the first embodiment.

FIG. 6 is a circuit diagram which schematically illustrates an active-matrix display device.

FIGS. 7A to 7D are drawings showing examples of electronic apparatuses using an electro-optical device.

### DESCRIPTION OF EXEMPLARY EMBODIMENTS

Embodiments of the invention will now be described in detail with references to the accompanying drawings. To omit the repetitive descriptions, like reference numerals designate like functional elements.

### First Embodiment

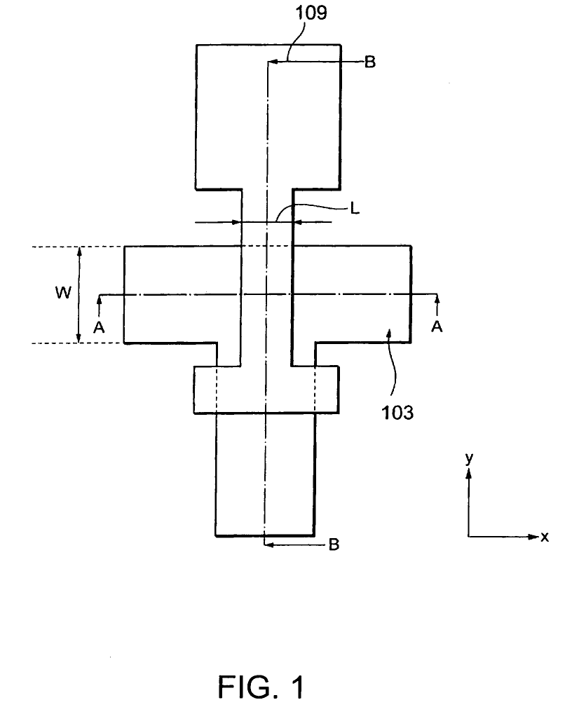

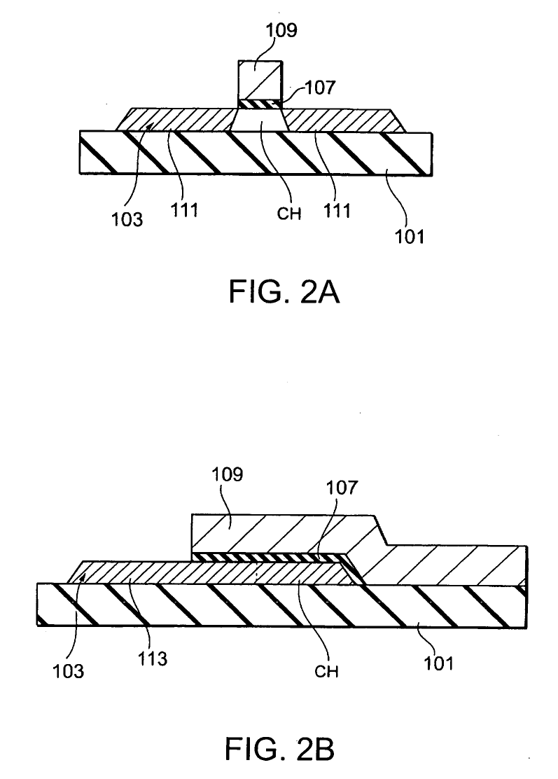

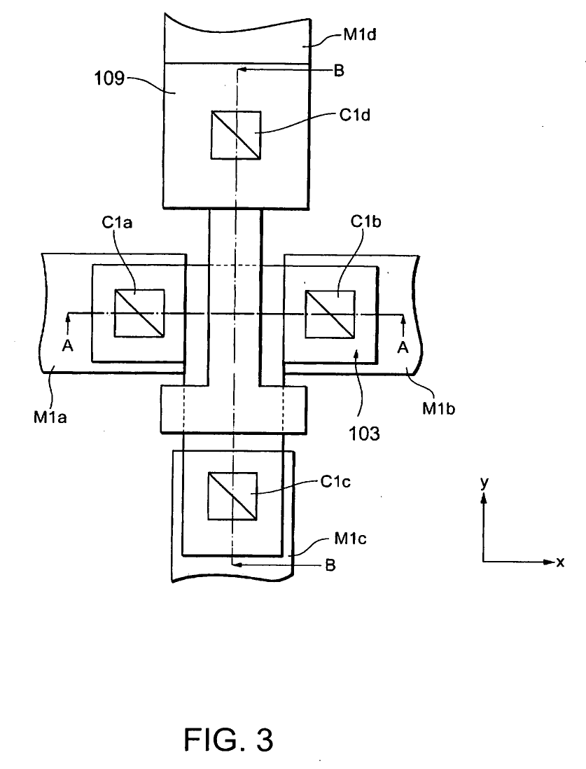

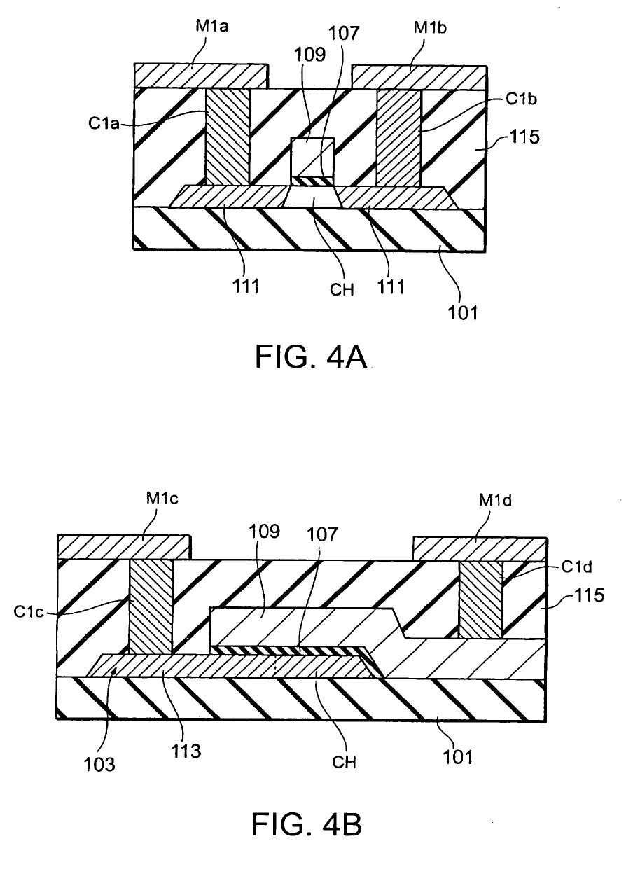

FIGS. 1 to 4 are either plan views or sectional views illustrating a structure of a thin film transistor (TFT) according to this embodiment. FIG. 1 and FIG. 3 are plan views and FIG. 2 and FIG. 4 are sectional views. FIGS. 2(A) and 2(B) respectively correspond to A-A and B-B sections in FIG. 1, and FIGS. 4(A) and 4(B) respectively correspond to A-A and B-B sections in FIG. 4.

As shown in FIGS. 1 and 2, the TFT according to this embodiment is formed on a semiconductor film 103 such as a glass substrate, the semiconductor film 103 being formed on a substrate 101 which has insulating and translucent properties. Here, a single-crystalline silicon film is used as the semiconductor film 103. A film thickness of this semiconductor film is, for instance, approximately 50 nm. An insulating substrate having a single-crystalline silicon film is called a SOQ (Silicon On Quartz) substrate, and is formed by, for instance, adhering the single-crystalline silicon film on the glass substrate.

This semiconductor film 103 in this embodiment has a shape of, in plan view, an island which is approximately T-shaped. As will be described later, source-drain regions 111 are arranged on both ends of a region extending in the x-direction, and a semiconductor region (body contact region) 113 is arranged at another end extended in the y-direction. Mesa isolation is used here, while an electric insulation from peripheral elements may also be achieved by an isolation insulating film. Examples of the isolation insulating film being used includes, for instance, a LOCOS (Local Oxidation of Silicon) film and a trench isolation film.

A gate electrode 109 is arranged over the semiconductor film 103, having a gate insulating film 107 therebetween. An oxide silicon film, for instance, is used as the gate insulating film 107. Moreover, a polysilicon film, for instance, is used as the gate electrode 109. Here, the gate electrode 109 is T-shaped in plan view. Conserving the symmetrical property of the gate electrode 109 with respect to the semiconductor film 103 (source-drain region) as described allows the usage of, for instance, a drive method of the common structure. As will be described later, the semiconductor region (body contact region) 113 is located at a first end of the T-shaped gate electrode in the y-direction, and a contact Cld is located at a second end. Here, the shape of the gate electrode 109 is not limited to a T-shape, and may include various modifications such as an H-shape in which a body contact is carried out from both sides.

Impurity ions are implanted in the semiconductor film 103 at both sides of the gate electrode 109, so as to form impurity regions. In case of an n-channel TFT, n-type impurity regions are arranged. These impurity regions become the source-drain regions 111 of a transistor. One of these becomes a source region, and the other becomes a drain region. The semiconductor film 103 located under the gate electrode 109 is called a channel region CH. In other words, the channel region CH is located between the source-drain regions 111.

Here, this channel region CH is adjacent to the semiconductor region (body contact region) 113 (refer to FIG. 2(B)). Withdrawing excess carriers generated in the channel region via the semiconductor region (body contact region) 113 reduces the substrate floating effect.

The TFT according to this embodiment is fully depleted. Being fully depleted means that the entire channel region CH of the semiconductor film 103 is depleted during the operation of the TFT. In contrast, a TFT that includes a neutral region remaining in the channel region CH is called a partially depleted type. In this embodiment, the channel region CH is a p-type semiconductor layer with a thickness of approximately 50 nm, and the impurity concentration is approximately 8*10¹⁴/cm³. In other words, a depleted region spreads to the entire semiconductor layer, therefore satisfying a full depletion condition.

Further, a gate length L and a gate width W of the gate electrode 109 is, for instance, approximately 0.6 μm and 20 μm (refer to FIG. 1).

Thereafter, as shown in FIGS. 3 and 4, an interlayer insulating film 115 is arranged on the gate electrode 109. This interlayer insulating film 115 is formed with, for instance, oxide silicon film, and contacts C1a through C1d are provided in the interlayer insulating film 115. The contacts C1a and C1b are arranged on the source-drain regions 111, and the contact C1c is arranged on the semiconductor region 113. Moreover, the contact C1d is arranged on the gate electrode 109. These contacts C1a through C1d are formed with a conductive material such as tungsten.

Further, first layer wirings M1a through M1d are respectively formed on these contacts C1a through C1d. The first layer wirings M1a and M1b are source and drain lead-out wirings and the M1d is a gate wiring. M1c is a body wiring, and in this case, a ground potential is applied. These first layer wirings M1a through M1d are formed with a conductive material such as metals.

As described, since the body contact region (semiconductor region 113) adjacent to the channel region of the fully depleted TFT is provided in this embodiment, and since this region is fixed to a predetermined potential (in this case, fixed to the ground potential), the substrate floating effect can be reduced.

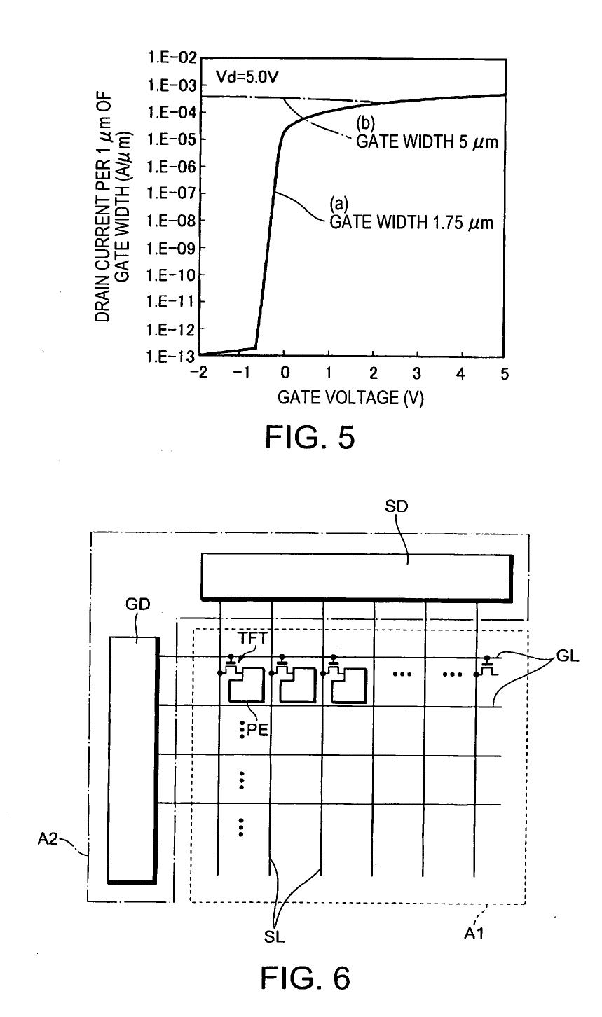

The effect of this embodiment will now be described with reference to FIG. 5. FIG. 5 is a diagram illustrating a transfer characteristic of the thin film transistor (TFT) according to this embodiment. The vertical axis represents a drain current [A/μm] per 1 μm gate width, and the horizontal axis represents a gate voltage [V]. A drain potential (source-drain potential) Vd is set to 5V. A film thickness of the gate oxidation film is 20 nm.

Graph (a) represents the transfer characteristic of the TFT with the body contact, having the gate width W of 1.75 μm and the gate length L of 0.6 μm. As illustrated, the drain current starts to flow when exceeding the predetermined gate voltage, which shows that the switching operation is possible. In contrast, if the gate length L stays as 0.6 μm while the gate width W is 5 μm (comparative example), graph (b) shows that a large current flows during the off time and therefore the comparative example does not operate as a transistor.

In other words, while it has been said that carrier removal has no effect in fully depleted transistors, according to the study of the inventor, even in the fully depleted transistors, if the gate width W is small to a certain extent, then it is considered that the body contact can remove the excess carriers that have rapidly increased transitorily due to the parasitic bipolar.

For instance, the effect of the body contact is obtained by setting the gate width W to be not greater than three times the gate length L (W≦3 L), in a fine TFT which is driven at the drain voltage greater than or equal to 3V and has the gate width not greater than 3 μm. In other words, the substrate floating effect of the channel region CH can be reduced and the desired switching operation is carried out. That is to say, an off leak can be reduced. Moreover, driving in a high drain potential (source-drain potential) is sustainable. In other words, the breakdown voltage between the source and the drain can be improved.

According to another study by the inventor, since the body contact effect was not confirmed for the gate width W that is over five times the gate length L, it is preferable that the body contact structure according to this embodiment be used in a TFT that has the gate width W which is not greater than five times, or, preferably, not greater than three times the gate length L.

While the description in this embodiment uses the n-channel TFT as an example, the present invention may also be applied to a p-channel TFT. In this case, a power potential is applied to the body wiring M1c.

Further, while the description in this embodiment uses the single-crystalline silicon film as an example of the semiconductor film 103, it is considered that miniaturization increases the substrate floating effect even in the case of using a polycrystalline silicon film that has a high crystalline property. Therefore, the invention may also be applied to the case of using the polycrystalline silicon film as the semiconductor film 103. However, since the substrate floating effect tends to occur in the single-crystalline silicon, the invention is effective when single-crystalline silicon is used.

Moreover, while the description in this embodiment uses the TFT formed on the semiconductor film 103 on the insulating substrate 101, the invention may also be applied to a transistor formed on a semiconductor film arranged over a semiconductor substrate having an insulating layer therebetween.

### Second Embodiment

This embodiment describes the application of the TFT described in the first embodiment to active matrix display devices.

FIG. 6 is a circuit diagram which schematically illustrates the active-matrix display device. As shown, each unit pixel region partitioned by a source line (wirings) SL and a gate line GL is arranged in an array in a pixel region A1. A TFT and a pixel electrode PE are arranged in the unit pixel region. One end of the TFT (source region) is coupled with the source line SL, and the other end (drain region) is coupled with the pixel electrode PE. Moreover, the gate electrode of the TFT is coupled with the gate line GL. The gate electrode may be the gate line GL.

The TFT described in detail in the first embodiment is applied to be the TFT that is aligned in an array. That is to say, a body contact is provided to each TFT. In other words, the semiconductor region (body contact region) is provided adjacently to the channel region of the TFT, and a fixed potential (in the case of the n-type TFT, a ground potential) is applied to this region. The gate electrode width of the TFT is scaled with the gate width W being, for instance, not greater than 3 μm, and not greater than five times, or, preferably, three times the gate length L.

As described, according to this embodiment, the substrate floating effect is reduced in each TFT, as is described in detail in the first embodiment. Consequently, properties of the display device can be improved. For instance, the gate electrode is miniaturized, enabling a high-speed operation. Moreover, the TFT can comply with driving in a high potential drain voltage. Particularly, while it is necessary to apply a high potential to pixel electrodes in a display device that uses liquid crystal and the like, the TFT is operable even when a high potential that is greater than or equal to 3V or 5V is applied to the pixel electrode, i.e. the drain electrode of the TFT, if the TFT described in detail in the first embodiment is included.

Further, as shown in FIG. 6, a peripheral circuit region A2 is provided in the perimeter of the pixel region A1. In such region, circuits (peripheral circuits) necessary for driving the pixels, such as a gate driver GD and a source driver SD, are formed. Such circuits are configured with, for instance, logic circuits, and are formed by appropriately coupling elements such as n-channel TFT and p-channel TFT.

The TFTs constituting such peripheral circuits endures a relatively less restrained design rules, such as no body contact region being provided, while the gate length is equal to or greater than 2 μm so that the fully depleted TFTs are prevented from the substrate floating effect. In other words, the channel regions (bodies) are in a floating state.

Further, in the peripheral circuits, by not employing the body contact structure, a common circuit layout can be used as is, without increasing a surface area of the peripheral circuit region. Moreover, the existing design tools and manufacturing processes can be employed.

As described, by providing the body contact region only to the TFTs in the pixel region A1, reducing the off leak is achieved even with a fine gate length. Here, the miniaturization allows the pixels to obtain a higher drive capacity even when driven in the high potential drain voltage. Therefore, the TFT according to an aspect of the invention is suitable as the pixel transistor.

Description of Electro-optical Device and Electronic Apparatus

The electro-optical device in which the aforementioned TFT and the display device are used will now be described.

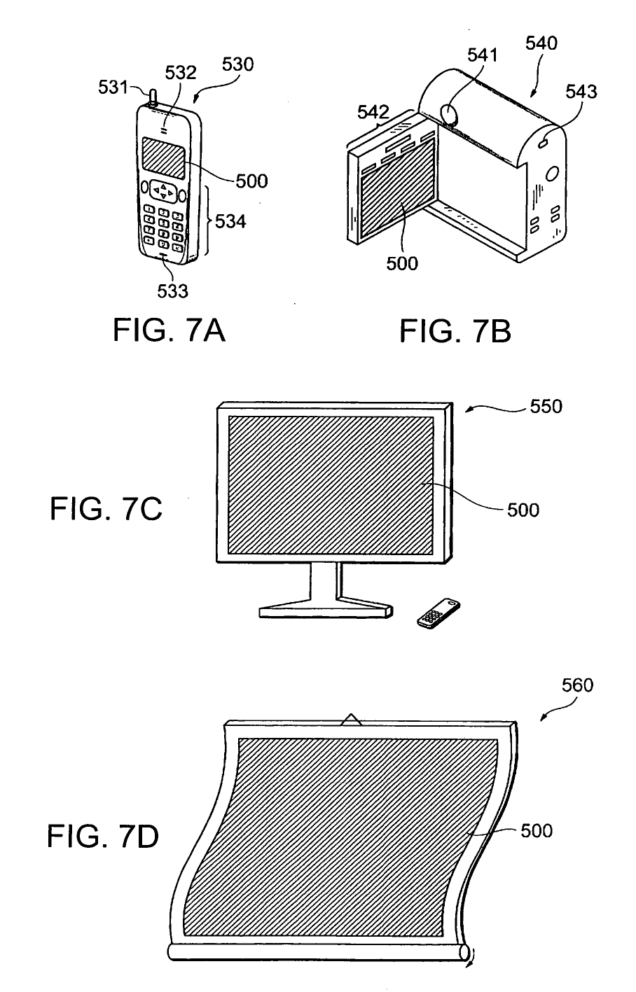

The TFT and the display device according to the aspects of the invention are used, for instance, in the liquid crystal panel that functions as a display unit of an electro-optical device or an electronic apparatus. Examples of the electronic apparatus using the electro-optical device are shown in FIG. 7.

FIG. 7A is an example of an application to a mobile phone, and FIG. 7(B) is an example applied to a video camera. Moreover, FIG. 7(C) is an example of an application to a television (TV), and FIG. 7(D) is an example of an application to a roll-up television.

As shown in FIG. 7(A), a mobile phone 530 includes an antenna 531, a sound output unit 532, a sound input unit 533, an operation unit 534, and an electro-optical device (display unit) 500. The TFT and the display device described in detail in one of the first embodiment and in the second embodiment may be used in this electro-optical device.

As shown in FIG. 7(B), a video camera 540 includes a receiver 541, an operation unit 542, a sound input unit 543, and the electro-optical device (display unit) 500. The TFT and the display device described in detail in one of the first embodiment and in the second embodiment may be used in this electro-optical device.

As shown in FIG. 7(C), a television 550 is provided with the electro-optical device (display unit) 500. The TFT and the display device described in detail in one of the first embodiment and in the second embodiment may be used in this electro-optical device. The TFT and the display device described in detail in the first embodiment and in the second embodiment may be used also for a monitor device (electro-optical device) used in a personal computer and the like.

As shown in FIG. 7(D), a roll-up television 560 is provided with the electro-optical device (display unit) 500. The TFT and the display device described in detail in one of the first embodiment and in the second embodiment may be used in this electro-optical device.

Other examples of the electronic apparatus provided with the electro-optical device include: a fax device with a display function, a view-finder of a digital camera, a mobile TV, an electronic notebook, an electrical bulletin board, and a display for advertising.

The invention is not limited to the descriptions of the above-referenced embodiments, and the examples and applications thereof described throughout the above-described embodiments may be optionally combined according to the application, and can be used with modification or refinement. It is obvious from the description in the claims that embodiments including such a combination, a modification, or a refinement may also fall within the technical scope of the invention.

1. A thin film transistor which is fully depleted, comprising:
an insulator;
a gate electrode;
a semiconductor film located between the insulator and the gate electrode; and
a gate insulating film located between the semiconductor film and the gate electrode, the semiconductor film including a source region, a drain region, a channel region located between the source region and the drain region, as well as a body contact region adjacent to the channel region,
wherein a gate width of the gate electrode is not greater than five times a gate length, and
a source-drain potential of the thin film transistor is greater than or equal to 3V.

2. The thin film transistor according to claim 1, wherein the insulator is an insulating substrate.

3. The thin film transistor according to claim 1, wherein the insulator is a translucent substrate.

4. The thin film transistor according to claim 1, wherein the semiconductor film is a single-crystalline silicon film.

5. The thin film transistor according to claim 1, wherein the semiconductor film is a polycrystalline silicon film.

6. The thin film transistor according to claim 1, wherein a predetermined potential is applied to the body contact region.

7. The thin film transistor according to claim 1, wherein the gate width of the gate electrode is not greater than three times the gate length.

8. The thin film transistor according to claim 1, wherein the gate width of the gate electrode is not greater than 3 μm.

9. The thin film transistor according to claim 1, wherein the source-drain potential of the thin film transistor is greater than or equal to 5V.

10. The thin film transistor according to claim 1, wherein the gate electrode has one of a T-gate structure and an H-gate structure.

11. A display device, comprising:
a thin film transistor which is fully depleted;
a gate wiring;
a source wiring; and
a pixel electrode,
wherein the thin film transistor includes a semiconductor film, a gate electrode, and a gate insulating film located between the semiconductor film and the gate electrode, the semiconductor film including a source region, a drain region, a channel region located between the source region and the drain region, and a body contact region adjacent to the channel region;
the gate wiring electrically couples the gate electrode;
the source wiring electrically couples the source region; and
the pixel electrode electrically couples the drain region.

12. A display device including a pixel region having a plurality of pixels and a peripheral circuit region in which a circuit for driving the pixels is formed, the display device comprising:
a first thin film transistor which is fully depleted and is coupled between a pixel electrode and a wiring, the first thin film transistor arranged to each of the pixels; and
a second thin film transistor constituting the circuit,
wherein the first and the second thin film transistors each include a gate electrode formed over a semiconductor film on an insulator, a gate insulating film included therebetween, a source and a drain regions formed in the semiconductor film at both sides of the gate electrode, and a channel region located between the source and the drain regions; and while the first thin film transistor includes a body contact region adjacent to the channel region, the second thin film transistor does not include the body contact region.
